(19) United States
(12) Patent Application Publication
(10) Pub. No.: US 2026/0068026 A1
(43) Pub. Date: Mar. 5, 2026

(54) PARTICLE ACCELERATOR HAVING CONFIGURABLE QUADRUPOLE ASSEMBLY

(71) Applicant: Applied Materials, Inc., Santa Clara, CA (US)

(72) Inventors: Wai Ming Tam, Georgetown, MA (US); William Herron Park, JR., Marblehead, MA (US); Scott E. Peitzsch, Tewksbury, MA (US)

(73) Assignee: Applied Materials, Inc., Santa Clara, CA (US)

(21) Appl. No.: 18/818,992

(22) Filed: Aug. 29, 2024

(51) Int. Cl. H05H 7/04; H01J 37/08; H01J 37/317; H05H 7/22; H05H 9/00

(52) U.S. Cl. CPC H05H 7/04; H01J 37/08; H01J 37/3171; H05H 7/22; H05H 9/00; H01J 2237/04732; H05H 2007/041; H05H 2277/12

(57) ABSTRACT

An ion implanter. The ion implanter may include an ion source, to generate a continuous ion beam. The ion implanter may further include a linear accelerator, comprising a buncher, to receive the continuous ion beam and generate a bunched ion beam, and further comprising a plurality of acceleration stages, arranged to receive the bunched ion beam and accelerate the bunched ion beam. The ion implanter may also include a plurality of quadrupoles, arranged in alternating fashion with the plurality of acceleration stages; and a plurality of quadrupole switch assemblies, coupled to the plurality of plurality of quadrupoles, respectively, wherein a given quadrupole switch assembly comprises a polarity switching circuit.

### FIELD OF THE DISCLOSURE

The disclosure relates generally to ion implantation apparatus and more particularly to high energy beamline ion implanters.

### BACKGROUND OF THE DISCLOSURE

Ion implantation is a process of introducing dopants or impurities into a substrate via bombardment. Ion implantation systems may comprise an ion source and a series of beam-line components. The ion source may comprise a chamber where ions are generated. The ion source may also comprise a power source and an extraction electrode assembly disposed near the chamber. The beam-line components, may include, for example, a mass analyzer, a first acceleration or deceleration stage, a collimator, and a second acceleration or deceleration stage. Much like a series of optical lenses for manipulating a light beam, the beam-line components can filter, focus, and manipulate ions or ion beam having particular species, shape, energy, and/or other qualities. The ion beam passes through the beam-line components and may be directed toward a substrate mounted on a platen or clamp.

Implantation apparatus capable of generating ion energies of approximately 1 MeV or greater are often referred to as high energy ion implanters, or high energy ion implantation systems. One type of high energy ion implanter is termed linear accelerator, or LINAC, where a series of electrodes arranged as drift tubes conduct and accelerate the ion beam to increasingly higher energy along the succession of tubes, where the electrodes receive a powered voltage signal. Known LINACs are driven by an RF voltage of frequency in the MHz-GHz range.

One issue for operation of RF LINAC ion implanters is that during acceleration of an ion beam, which ion beam is partitioned into ion bunches along a direction of propagation (Z-direction), a natural tendency of an ion bunch is to spread out both transversely (in X-direction and Y-direction) as well as longitudinally (in Z-direction, or equivalently, in time). RF LINACS may include components such as quadrupoles to shape and focus the ion bunches in an ion beam, such as DC quadrupoles that apply electric fields generally in a transverse direction to the direction of propagation of the ion bunches. The DC quadrupoles may be added at various stages along a LINAC, where a given stage includes a series of drift tubes that accelerate the ion bunch within gaps provided between adjacent drift tubes.

In known LINACS a quadrupole may be disposed between adjacent stages of a LINAC where a quadrupole field is applied that focuses the ion beam (the term ‘ion beam’ as used herein, in the context of a LINAC, may refer to a series of ion bunches that are separated in space and time) in a first direction, such as the X-direction, while defocusing the beam in a second direction, orthogonal to the first direction (such as the Y-direction). In order to properly focus and shape an ion beam, known LINACs may employ a specific sequence of quadrupoles where focusing of the ion beam may take place at a first quadrupole, and defocusing of the ion beam takes place at another quadrupole that lies downstream or upstream of the first quadrupole.

The sequence of focusing and defocusing performed by a series of quadrupoles in a LINAC may depend upon the number of stages in a LINAC, the ion energy of ion bunches, and other factors. Thus, a given ion implanter will be fabricated with a predetermined arrangement of quadrupoles that set a focusing-defocusing (FODO) sequence for the quadrupoles along the length of the LINAC. Note that for any given quadrupole focusing in the X-direction will imply defocusing in the Y direction. Thus, a 4-stage LINAC that includes 4 quadrupoles and sets a sequence of FODOFODO will generate quadrupole fields along a given direction (such as the X-direction) that alternately focus the ion bunch in the X-direction (at a first quadrupole) and then defocus (at a second quadrupole), immediately downstream of the first quadrupole, and then focus (at a third quadrupole), immediately downstream to the second quadrupole, etc. In the above scheme, along the Y-direction, the ion bunch will be first defocused, then focused, then defocused, and so forth.

In some known LINAC arrangements, a FODOFODO scheme may be employed to process an ion beam. To properly shape an ion beam, this LINAC configuration requires relatively higher focusing strength at each quadrupole, entailing either the use of a longer quadrupole, requiring a larger tool footprint, or alternatively, a higher voltage being applied to quadrupole electrodes, leading to worse reliability.

In other known LINAC arrangements a FOFODODO scheme may be employed. To properly shape an ion beam, this latter LINAC configuration results in a relatively longer focusing period along the LINAC and entails a lower focusing strength for a given quadrupole as opposed to the FODOFODO configuration, with a tradeoff in beam quality.

In view of the above, the presently known quadrupole configurations present advantages and disadvantages in terms of performance, reliability, and size.

With respect to these and other considerations the present disclosure is provided.

### BRIEF SUMMARY

In one embodiment, an ion implanter is provided. The ion implanter may include an ion source, to generate a continuous ion beam. The ion implanter may further include a linear accelerator, comprising a buncher, to receive the continuous ion beam and generate a bunched ion beam, and further comprising a plurality of acceleration stages, arranged to receive the bunched ion beam and accelerate the bunched ion beam. The ion implanter may also include a plurality of quadrupoles, arranged in alternating fashion with the plurality of acceleration stages; and a plurality of quadrupole switch assemblies, coupled to the plurality of plurality of quadrupoles, respectively, wherein a given quadrupole switch assembly comprises a polarity switching circuit.

In another embodiment, a control arrangement for operating a linear accelerator is provided. The control arrangement may include a plurality of quadrupole switch assemblies, coupled to a plurality of quadrupoles, respectively, the plurality of quadrupoles being arranged in alternating fashion with a plurality of acceleration stages of the linear accelerator. As such, a given quadrupole switch assembly may include a quadrupole polarity switch circuit, arranged to switch a polarity of a given quadrupole of the plurality of quadrupoles; and a switch controller, coupled to the quadrupole polarity switch circuit. The switch controller may include a processor, and a memory unit coupled to the processor, including a quadrupole switching routine, the quadrupole switching routine operative on the processor to control the quadrupole polarity switch circuit to switch the given quadrupole from a focus configuration to a defocus configuration.

In a further embodiment, a method of operating an ion implanter is provided. The method may include receiving an ion implantation recipe for implementing in the ion implanter, the ion implanter comprising a multi-stage linear accelerator having a plurality of quadrupoles; receiving a current quadrupole configuration for the plurality of quadrupoles; receiving a current quadrupole voltage profile, comprising a plurality of voltages that are applied to electrodes of the plurality of quadrupoles, respectively; and adjusting the current quadrupole configuration by sending at least one control signal to one or more quadrupole switch assemblies of the linear accelerator, when the current quadrupole voltage profile exceeds a determined threshold.

### BRIEF DESCRIPTION OF THE DRAWINGS

FIG. 1A shows an embodiment of an ion implanter;

FIG. 1B depicts a controller for controlling a linear accelerator;

FIG. 1C depicts an exemplary quadrupole configuration;

FIG. 2 depicts one embodiment of a quadrupole switch assembly;

FIG. 3A depicts another embodiment of a quadrupole switch assembly;

FIG. 3B depicts another embodiment of a quadrupole switch assembly;

FIG. 3C depicts a schematic representation of another exemplary quadrupole configuration;

FIG. 4A shows one configuration of a linear accelerator having switchable quadrupoles;

FIG. 4B shows another configuration of a linear accelerator having switchable quadrupoles;

FIG. 5A shows quadrupole applied voltage as a function of position along a linear accelerator for one ion implantation recipe;

FIG. 5B shows quadrupole applied voltage as a function of position along a linear accelerator for another ion implantation recipe; and

FIG. 6 depicts one exemplary process flow.

### DETAILED DESCRIPTION

An apparatus, system and method in accordance with the present disclosure will now be described more fully hereinafter with reference to the accompanying drawings, where embodiments of the system and method are shown. The system and method may be embodied in many different forms and are not to be construed as being limited to the embodiments set forth herein. Instead, these embodiments are provided so this disclosure will be thorough and complete, and will fully convey the scope of the system and method to those skilled in the art.

Terms such as “top,” “bottom,” “upper,” “lower,” “vertical,” “horizontal,” “lateral,” and “longitudinal” may be used herein to describe the relative placement and orientation of these components and their constituent parts, with respect to the geometry and orientation of a component of a semiconductor manufacturing device as appearing in the figures. The terminology may include the words specifically mentioned, derivatives thereof, and words of similar import.

As used herein, an element or operation recited in the singular and proceeded with the word “a” or “an” are understood as potentially including plural elements or operations as well. Furthermore, references to “one embodiment” of the present disclosure are not intended to be interpreted as precluding the existence of additional embodiments also incorporating the recited features.

Provided herein are approaches for improved high energy ion implantation systems and components, based upon a beamline architecture, and in particular, ion implanters based upon linear accelerators. For brevity, an ion implantation system may also be referred to herein as an “ion implanter.” Various embodiments entail novel approaches that provide the capability of improved control of an ion beam during acceleration through the acceleration stages of a linear accelerator, and in particular, improved ion beam focusing. In particular, configurable quadrupole assemblies are provided, where the arrangement of quadrupole configurations in a linear accelerator are reversibly and readily switchable using a switch controller.

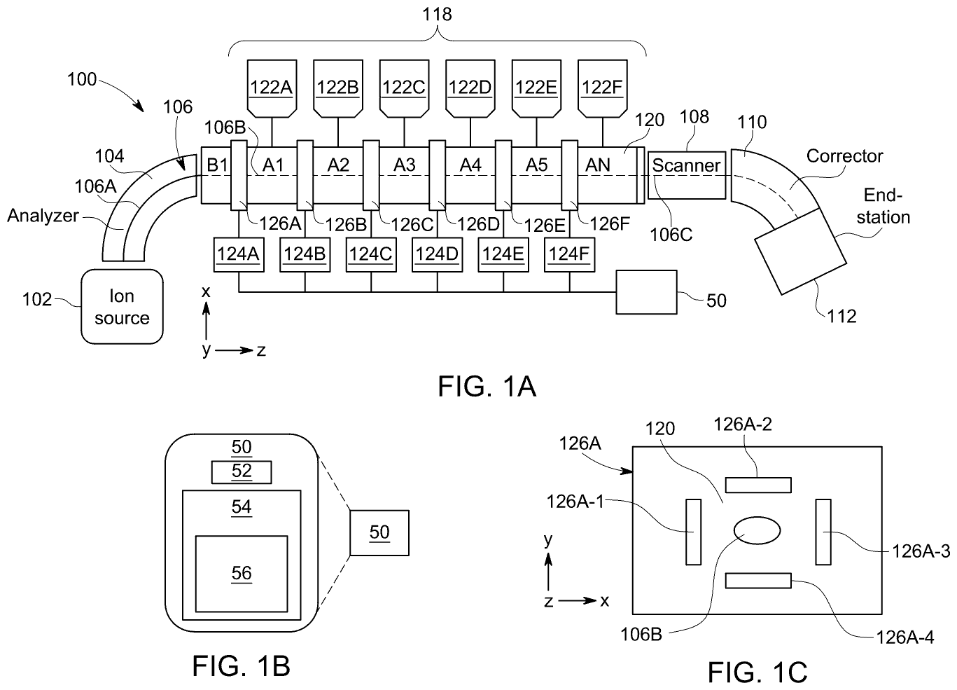

Referring now to FIG. 1A, an ion implanter 100 is shown in block form. The ion implanter 100 may represent a beamline ion implanter, with some elements not shown for clarity of explanation. The ion implanter 100 may include an ion source 102, an analyzer 104, as known in the art. The ion implanter 100 may represent a high energy ion implanter that is design to accelerate ions of a targeted ion species to a relatively higher energy, such as greater than 500 keV, greater than 1 MeV, or greater than 1.5 MeV. According to various embodiments of the disclosure, the ion implanter 100 may be designed to efficiently generate high energy ion beams for ion species over a large mass range, such as from protons up to m/q ratios of 20 or more. In addition to a linear accelerator 118, the ion implanter 100 may include a scanner 108, corrector 110, and end station 112, as known in the art. The linear accelerator 118 may include a vacuum enclosure 120 that encloses multiple internal components, such as drift tubes and quadrupoles (not separately shown) as known in the art. The vacuum enclosure 120 may form a backbone of the linear accelerator 118.

As depicted in FIG. 1A, the linear accelerator 118 may be characterized by a plurality of acceleration stages. Merely for the purposes of illustration, these stages are shown as stage A1, stage A2, stage A3, stage A4, stage A5, stage AN, where N is any suitable integer. Thus, while 6 acceleration stages are depicted, in other embodiments, a linear accelerator may include fewer or a larger number of acceleration stages.

A given acceleration stage may be characterized by a power assembly that provides an RF voltage to a set of electrodes that are arranged inside the vacuum enclosure 120 as a series of drift tubes that conduct an ion beam therethrough. The power assemblies for the respective acceleration stages are shown as power assembly 122A, power assembly 122B, power assembly 122C, power assembly 122D, power assembly 122E, and power assembly 122F in the example of FIG. 1A. The different power assemblies may represent RF power supplies, circuits, and resonators to apply an RF voltage signal to each acceleration stage, as known in the art.

When an ion beam 106A is generated by the ion source 102, the ion beam 106A will enter the linear accelerator 118 as a continuous ion beam, and will be processed by a buncher B1 to generate a bunched ion beam 106B. The bunched ion beam 106B will be accelerated through the linear accelerator 118 according to the amplitude of voltage that is applied to the acceleration stages of the linear accelerator 118. The voltage applied to a given acceleration stage will generate an RF field across gaps between drift tube electrodes that are arranged with each acceleration stage, as known in the art. For example, a double gap acceleration stage may include one powered drift tube that is coupled to receive an RF signal from an RF power supply, as well as a pair of grounded drift tubes, as known in the art. A triple gap acceleration stage may include two powered drift tubes, adjacent to one another, as well as a pair of grounded drift tubes, and so forth. The voltage may be applied to a given powered drift tube via a resonator coil that is disposed in a resonator chamber of a resonator as known in the art.

Thus, as the bunched ion beam 106B is conducted through the linear accelerator 118, the bunched ion beam 106B will be accelerated through a plurality of steps to higher and higher energy that is proportional to the number of acceleration stages, the maximum voltage amplitude of the RF voltage applied to each stage, the charge of the ions of the bunched ion beam 106B, among other factors. The bunched ion beam 106B will then emerge from the linear accelerator 118 as the high energy ion beam 106C, where the final energy of the high energy ion beam 106C may be on the order of 500 keV, 1 MeV, or higher.

As further shown in FIG. 1A, the linear accelerator 118 may include a plurality of quadrupole elements that may be referred to herein simply as ‘quadrupoles.’ As shown in FIG. 1A, a quadrupole 126A is disposed adjacent to stage A2, a quadrupole 126B is disposed between stage A1 and stage A2, a quadrupole 126C is disposed between stage A2 and stage A3, a quadrupole 126D is disposed between stage A3 and stage A4, a quadrupole 126E is disposed between stage A4 and stage A5, and a quadrupole 126F is disposed between stage A5 and stage AN, and so forth. These quadrupoles are used to focus/steer the ion beam as the ion beam moves through the linear accelerator 106. In some embodiments, the quadrupoles (126A-126F) may be electrostatic quadrupoles where a given quadrupole may apply an electric field(s) that extends generally along a transverse direction(s) to a direction of propagation of the bunched ion beam 106B. In some embodiments, the quadrupoles (126A-126F) may be electromagnetic quadrupoles that apply magnetic fields transvers to the direction of propagation of the bunched ion beam 106B.

Depending upon the transverse electric field applied by a given quadrupole along a given transverse direction, the electric field will tend to focus or defocus the bunched ion beam 106B. For example, using the Cartesian coordinate system shown, the bunched ion beam 106B may be conducted along the z-direction, while the quadrupole 126A focuses the bunched ion beam 106B along the x-direction, and defocuses the bunched ion beam 106B along the y-direction. On the other hand, the quadrupole 126B may defocus the bunched ion beam 106B along the x-direction, and focus the bunched ion beam 106B along the y-direction. According to the present embodiments, the arrangement of quadrupole configurations of the linear accelerator 118 may be reversibly switched according to certain considerations.

As further depicted in FIG. 1A, the linear accelerator 118 includes a plurality of quadrupole switch assemblies that are individually coupled to the plurality of quadrupoles, respectively. These quadrupole switch assemblies are shown as quadrupole switch assembly 124A, coupled to quadrupole 126A, quadrupole switch assembly 124B, coupled to quadrupole 126B, quadrupole switch assembly 124C, coupled to quadrupole 126C, quadrupole switch assembly 124D, coupled to quadrupole 126D, quadrupole switch assembly 124E, coupled to quadrupole 126E, quadrupole switch assembly 124F, coupled to quadrupole 126F. The operation of these quadrupole switch assemblies is detailed with respect to the figures to follow.

In brief, a controller 50 (see FIG. 1B), which controller may include a plurality of controllers and may act as a system controller, is provided to control the configuration of quadrupoles in the linear accelerator 118. A given quadrupole may include two pairs of poles that act to establish a quadrupole field. In the case of electrostatic quadrupoles the two pairs of poles may be two pairs of electrodes that act to establish electric fields, where such electric fields are established by generating a common voltage at a first pair of opposing electrodes, and a second voltage at a second pair of opposing electrodes. In an embodiment of an electromagnetic quadrupole, each pole may be an electromagnet. In one example, as shown in FIG. 1C, the quadrupole 126A may include a pole formed at an electrode 126A-1 that is paired with a pole that is formed at electrode 126A-3. In the case of electrostatic poles, at a given configuration, a positive voltage may be applied to electrode 126A-1 and electrode 126A-3 while a negative voltage is applied to the electrode 126A-2 and electrode 126A-4, to generate a quadrupole electric field. In particular embodiments, the various poles (electrodes 126A-1 to 126A-4) may be arranged such that adjacent poles are equidistant from one another.

According to the present embodiments, the controller 50 may act to reversibly switch the configuration of voltages applied to the electrodes of a given quadrupole, so as to change the effect of fields generated by the given quadrupole. Thus, in a first configuration, the quadrupole 126A may be arranged to generate a focusing field (FO) along the X-direction, while in a second configuration, the quadrupole 126A is arranged to generate a defocusing field along the X-direction.

These changes are accomplished by the provision of the quadrupole switch assemblies as detailed herein.

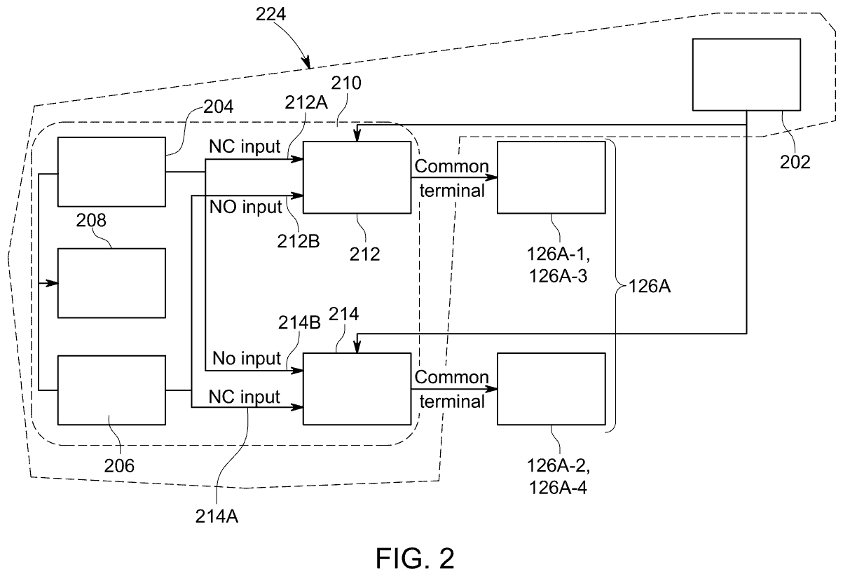

FIG. 2 depicts one embodiment of a quadrupole switch assembly. For purposes of illustration, the quadrupole switch assembly 224 may be assumed to be one variant of the quadrupole switch assemblies shown in FIG. 1. In particular, the quadrupole switch assembly 224 may be considered to be a variant of the quadrupole switch assembly 124A. Thus, for the purposes of illustration of FIG. 2, the quadrupole switch assembly 224 is coupled to control the quadrupole 126A. However, the quadrupole switch assembly 224 may be a variant of the quadrupole switch assembly 124B, the quadrupole switch assembly 124C, and so forth. Thus, the arrangement of quadrupole switch assembly 224 may apply to any other quadrupole switch assembly of the linear accelerator 118, for the purposes of controlling any other quadrupole of linear accelerator 118.

Generally, the quadrupole switch assembly 224 (as well as a quadrupole switch assembly 324, to be discussed) may include a switch controller that is coupled to a given quadrupole, and a quadrupole switch control circuit that is arranged to switch a polarity of a set of electrodes on a given quadrupole, such as a voltage polarity. The quadrupole switch assembly 224 may be embodied in any suitable combination of hardware and software. As shown, a switch controller 202 is provided for coupling to a given quadrupole (in this case, quadrupole 126A), as well as a quadrupole polarity switch circuit 210, that is arranged to switch a polarity of a set of electrodes on the given quadrupole, in this case, electrodes of quadrupole 126A.

Before detailing the workings of the quadrupole switch assembly 224, note that the switch controller 202 is arranged to switch the quadrupole 126A from a focus configuration to a defocus configuration. Note that the terms ‘focus configuration’ and ‘defocus configuration’ is applied to a given focusing direction, such that in the focus configuration a given quadrupole focuses an ion beam along a first direction, and in the defocus configuration, the given quadrupole defocuses the bunched ion beam along the first direction. Thus, the switch controller 202 will function to alternately set the quadrupole 126A to focus an ion beam along the x-direction or to defocus the ion beam along the x-direction. In such circumstances, when the quadrupole 126A is controlled to switch from focusing the ion beam along the x-direction to defocusing the ion beam along the y-direction, the quadrupole 126A will switch from defocusing the ion beam along the y-direction to focusing the ion beam along the y-direction.

As shown in FIG. 2, the quadrupole polarity switch circuit 210 includes a positive voltage supply 204 to output a positive voltage, and a negative voltage supply 206 to output a negative voltage. The quadrupole polarity switch circuit 210 also includes a first switch 212 that is coupled to a first pair of opposing electrodes of the quadrupole 126A. For the purposes of illustration, the first pair of opposing electrodes may be deemed electrode 126A-1, and electrode 126A-3, where these two electrodes may be coupled to receive a same voltage at a same time. Likewise, the quadrupole polarity switch circuit 210 may include a second switch 214 that is coupled to a second pair of opposing electrodes of the quadrupole 126A. For the purposes of illustration, the second pair of opposing electrodes may be deemed electrode 126A-2, and electrode 126A-4, where these two electrodes may be coupled to receive a same voltage at a same time. In order to establish a quadrupole configuration, the electrode 126A-1 and electrode 126A-3 will receive a common voltage at a given configuration, such as a positive voltage, while the electrode 126A-2 and electrode 126A-4 will receive a second common voltage, such as a negative voltage.

Note that the positive voltage supply 204 is directly coupled to the first switch 212, to the second switch 214, and to a chassis ground 208, while the negative voltage supply 206 is also directly coupled to the first switch 212, to the second switch 214 and to the chassis ground 208. Note further that the first switch 212 includes a normally closed input 212A and a normally open input 212B, and the second switch 214 includes a normally closed input 214A and a normally open input 214B. As shown in FIG. 2, the normally closed input 212A of the first switch 212 is coupled to the normally open input 214B of the second switch 214; and the normally open input 212B of the first switch 212 is coupled to the normally closed input 214A of the second switch 214. Note further that the positive voltage supply 204 is connected to the normally closed input 212A of the first switch 212 and to the normally open input 214B, while the negative voltage supply 206 is coupled to the normally open input 212B of the first switch 212 and to the normally closed input 214A of the second switch 214. In the default configuration, the positive voltage supply 204 is connected to electrode 126A-1 and electrode 126A-3, while the negative voltage supply 206 is connected to electrode 126A-2 and electrode 126A-4 through the Normally Closed (NC) terminal of the relays (first switch 212 and second switch 214, respectively). Polarity is reversed by enabling relays (first switch 212 and second switch 214), resulting in the positive voltage supply 204 being connected to electrode 126A-2 and electrode 126A-4 and the negative supply being connected to electrode 126A-1 and electrode 126A-3 through the Normally Open (NO) terminal of relays (first switch 212 and second switch 214, respectively).

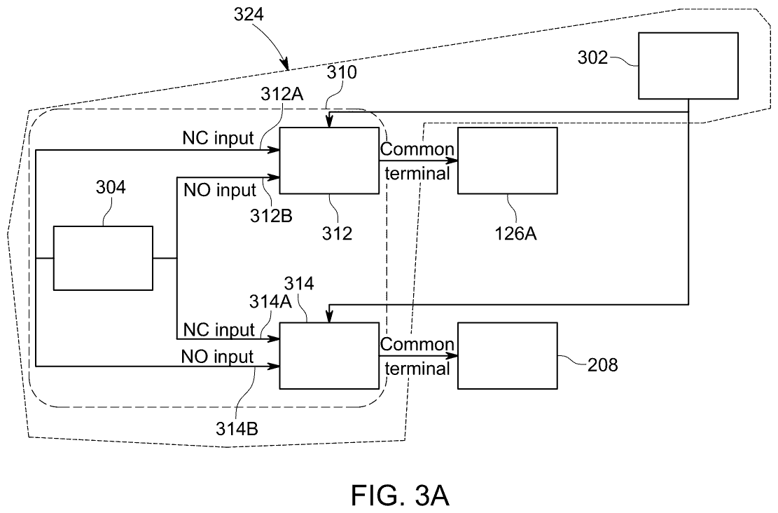

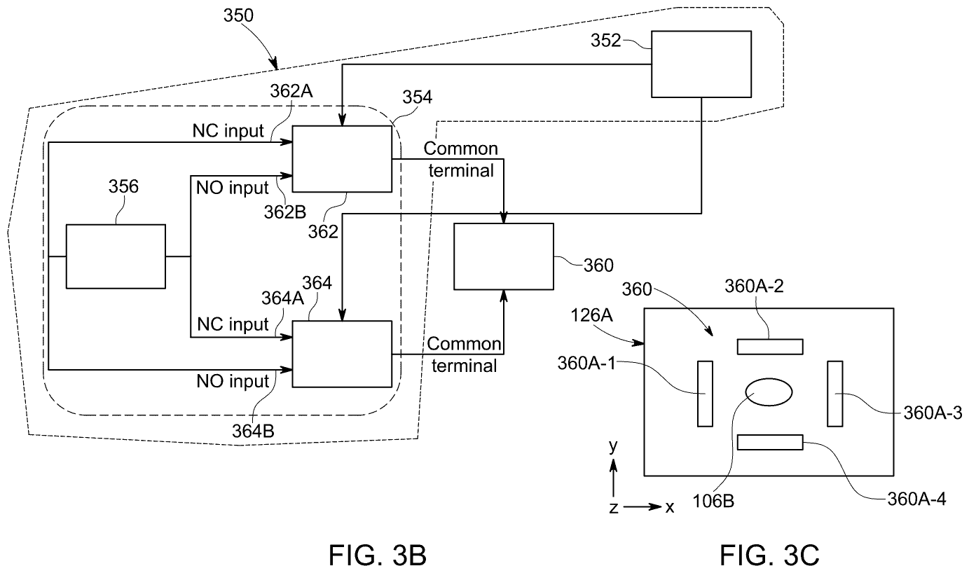

FIG. 3A depicts another embodiment of a quadrupole switch assembly 324. For purposes of illustration, the quadrupole switch assembly 324 may be assumed to be another variant of the quadrupole switch assemblies shown in FIG. 1. In particular, the quadrupole switch assembly 324 may be considered to be a variant of the quadrupole switch assembly 124A. Thus, for the purposes of illustration of FIG. 3A, the quadrupole switch assembly 324 is coupled to control the quadrupole 126A. However, the quadrupole switch assembly 324 may be a variant of the quadrupole switch assembly 124B, the quadrupole switch assembly 124C, and so forth. Thus, the arrangement of quadrupole switch assembly 324 may apply to any other quadrupole switch assembly of the linear accelerator 118, for the purposes of controlling any other quadrupole of linear accelerator 118.

Generally, the quadrupole switch assembly 324 may include a switch controller that is coupled to a given quadrupole, and a quadrupole switch control circuit that is arranged to switch a polarity of a set of electrodes on a given quadrupole. The quadrupole switch assembly 324 may be embodied in any suitable combination of hardware and software. As shown, a switch controller 302 is provided for coupling to a given quadrupole (in this case, quadrupole 126A), as well as a quadrupole polarity switch circuit 310, that is arranged to switch a polarity of a set of electrodes on the given quadrupole, in this case, electrodes of quadrupole 126A.

Before detailing the workings of the quadrupole switch assembly 324, note that the switch controller 302 is arranged to switch the quadrupole 126A from a focus configuration to a defocus configuration. Similarly to switch controller 202, the switch controller 302 will function to alternately set the quadrupole 126A to focus an ion beam along the x-direction or to defocus the ion beam along the x-direction. In such circumstances, when the quadrupole 126A is controlled to switch from focusing the ion beam along the x-direction to defocusing the ion beam along the y-direction, the quadrupole 126A will switch from defocusing the ion beam along the y-direction to focusing the ion beam along the y-direction.

As shown in FIG. 3A, the quadrupole polarity switch circuit 310 includes a floating voltage supply 304 to output a positive voltage or a negative voltage. The quadrupole polarity switch circuit 310 also includes a first switch 312 that is coupled to the quadrupole 126A. The quadrupole polarity switch circuit 310 may include a second switch 314 that is coupled to a chassis ground 208. In order to establish a quadrupole configuration, the electrode 126A-1 and electrode 126A-3 will receive a common voltage at a given configuration, such as a positive voltage, while the electrode 126A-2 and electrode 126A-4 will receive a second common voltage, such as a negative voltage.

Note that the floating voltage supply 304 is directly coupled to the first switch 312, to the second switch 314. Note further that the first switch 312 includes a normally closed input 212A and a normally open input 312B, and the second switch 314 includes a normally closed input 314A and a normally open input 314B. As shown in FIG. 3, the normally closed input 312A of the first switch 312 is coupled to the normally open input 314B of the second switch 314; and the normally open input 312B of the first switch 312 is coupled to the normally closed input 314A of the second switch 314. Note further that the floating voltage supply 304 is connected to the normally closed input 312A of the first switch 312 and to the normally open input 314B, as well as to the normally open input 312B of the first switch 312 and to the normally closed input 314A of the second switch 314. In this configuration, floating voltage supply 304 provides a floating secondary output, such that either the positive terminal or negative terminal can be grounded, allowing the floating voltage supply 304 to act as either a positive or negative supply. In the default configuration, the negative terminal would be grounded to chassis ground 208 via the Normally Closed (NC) terminal of relay/switch (second switch 314) and the positive terminal would be connected to one pair of electrodes of the quadrupole 126A via the Normally Closed (NC) terminals of relay/switch (first switch 312). Polarity is reversed to this electrode pair by enabling relay/switches (first switch 312 and second switch 314), thus grounding the positive terminal of floating voltage supply 304 through the Normally Open (NO) contact of relay/switch (second switch 314) and connecting the negative terminal of floating voltage supply 304 to the electrode pair of quadrupole 126A through the Normally Open (NO) contacts of relay/switch (first switch 312).

FIG. 3B depicts another embodiment of a quadrupole switch assembly 350. For purposes of illustration, the quadrupole switch assembly 350 may be assumed to be another variant of the quadrupole switch assemblies shown in FIG. 1. In this case, for the purposes of illustration of FIG. 3B, the quadrupole switch assembly 350 is coupled to control a magnetic quadrupole, shown as a quadrupole 360. Thus, the arrangement of quadrupole switch assembly 350 may apply to any other quadrupole switch assembly of the linear accelerator 118, for the purposes of controlling any other quadrupole of linear accelerator 118.

Generally, the quadrupole switch assembly 350 may include a switch controller that is coupled to a given quadrupole, and a quadrupole switch control circuit that is arranged to switch a polarity of a set of electrodes on a given quadrupole. The quadrupole switch assembly 350 may be embodied in any suitable combination of hardware and software. As shown, a switch controller 352 is provided for coupling to a given quadrupole (in this case, quadrupole 360), as well as a quadrupole polarity switch circuit 354, that is arranged to switch a polarity poles of the magnetic quadrupole, quadrupole 360. Switching of polarity takes place by reversing the current flow into magnetic coils of the quadrupole 360, as detailed below.

Before detailing the workings of the quadrupole switch assembly 350, note that the switch controller 352 is arranged to switch the quadrupole 360 from a focus configuration to a defocus configuration. Similarly to switch controller 352, the switch controller 302, will function to alternately set the quadrupole 360 to focus an ion beam along the x-direction or to defocus the ion beam along the x-direction. In such circumstances, when the quadrupole 360 is controlled to switch from focusing the ion beam along the x-direction to defocusing the ion beam along the y-direction, the quadrupole 360 will switch from defocusing the ion beam along the y-direction to focusing the ion beam along the y-direction.

As shown in FIG. 3B, the quadrupole polarity switch circuit 354 includes a floating high current supply 356 to output a current (amps). The quadrupole polarity switch circuit 354 also includes a first switch 362 that is coupled to the quadrupole 360. The quadrupole polarity switch circuit 354 may include a second switch 364 that is also coupled to the quadrupole 360. Referring also to FIG. 3C, in order to establish a quadrupole configuration, a coil 360A-1 and coil 360A-3 of the quadrupole 360 will receive a common current at a given configuration, such as a positive current, while the coil 360A-2 and coil 360A-4 will receive a second common current, such as a negative current.

Note that the floating high current supply 356 is directly coupled to the first switch 362, and to the second switch 364. Note further that the first switch 362 includes a normally closed input 362A and a normally open input 362B, and the second switch 364 includes a normally closed input 364A and a normally open input 364B. As shown in FIG. 3B, the normally closed input 362A of the first switch 362 is coupled to the normally open input 364B of the second switch 364; and the normally open input 362B of the first switch 362 is coupled to the normally closed input 364A of the second switch 364. Note further that the floating high current supply 356 is connected to the normally closed input 362A of the first switch 362 and to the normally open input 364B, as well as to the normally open input 362B of the first switch 362 and to the normally closed input 364A of the second switch 364.

In the embodiment of FIG. 3B, the switching logic of the quadrupole polarity switch circuit 354 will operate in the same manner as the logic of the quadrupole polarity switch circuit 310 or the quadrupole polarity switch circuit 210. Thus, to switch polarity in the quadrupole 360, the direction that the current flows into a set of magnetic coils, such as coil 36A-1 and coil 360A-2, is switched. The current supply has a fixed polarity, just as a voltage supply does. The relays (first switch 312 and second switch 314) shown in FIG. 3B allow the positive terminal of floating high current supply 356 to be connected to either side of quadrupole 360. This switching of in turn reverses the direction of the magnetic field established by the quadrupole 360.

Note that the secondary benefits of this embodiment are slightly different than the benefits flowing from the quadrupole polarity switch circuit 310 or the quadrupole polarity switch circuit 210. For an electrostatic quadruple, the respective quadrupole polarity switch circuits keep the maximum voltage on any given quadrupole to a lower level, so that an improvement in both performance and reliability is obtainable. Reduced voltage on the quadrupoles lowers the chances of reliability issues caused by voltage breakdown. For a magnetic quadrupole, the quadrupole polarity switch circuit 354 still allows for more optimal beam transmission while also minimizing heating of the quadrupoles and reducing overall power consumption.

According to various embodiments of the disclosure, a given quadrupole switch assembly (124A-124N) of a linear accelerator, such as linear accelerator 118, may control the quadrupole configuration of the given quadrupole. The given quadrupole switch assembly may perform in conjunction with a controller 50 to individually set the quadrupole configuration at a given quadrupole, while the controller 50 may globally control the pattern of quadrupole configurations across the entirety of the linear accelerator according to some embodiments.

FIG. 1B shows further details of the controller 50. In this embodiment, the controller 50 may include a processor 52, such as a known type of microprocessor, dedicated processor chip, general purpose processor chip, or similar device. The controller 50 may further include a memory or memory unit 54, coupled to the processor 52, where the memory unit 54 contains a quadrupole switching routine 56. In some embodiments, the processor 52 and memory unit 54 may be included in the switch controller 202 and in the switch controller 302.

The memory unit 54 may comprise an article of manufacture. In one embodiment, the memory unit 54 may comprise any non-transitory computer readable medium or machine readable medium, such as an optical, magnetic or semiconductor storage. The storage medium may store various types of computer executable instructions to implement one or more of logic flows described herein. Examples of a computer readable or machine-readable storage medium may include any tangible media capable of storing electronic data, including volatile memory or non-volatile memory, removable or non-removable memory, erasable or non-erasable memory, writeable or re-writeable memory, and so forth. Examples of computer executable instructions may include any suitable type of code, such as source code, compiled code, interpreted code, executable code, static code, dynamic code, object-oriented code, visual code, and the like. The embodiments are not limited in this context.

The quadrupole switching routine 56 may be operative on the processor 52 to control a given quadrupole polarity switch circuit to switch a given quadrupole of linear accelerator 118 from a focus configuration to a defocus configuration.

In some embodiments, the quadrupole switching routine 56 may be operative to switch a given quadrupole, responsive to user input, such as a user of the ion implanter 100. In some embodiment, the quadrupole switching routine 56 may be operative to switch a given quadrupole based upon a set of determined criteria. These criteria may include the maximum voltage amplitude of the RF voltage applied to the drift tube electrodes in each stage of a linear accelerator, the maximum voltage to be applied to quadrupole electrodes, a desired focusing characteristic of the bunched ion beam being conducted through the linear accelerator, and so forth.

In some embodiments, the quadrupole switching routine 56 may be operative on the processor 52 to control the plurality of quadrupole switch assemblies (124A-124N) to switch from a first focusing sequence to a second focusing sequence, where the second focusing sequence differs from the first focusing sequence in that at least one quadrupole is switched between the focus and the defocus configuration.

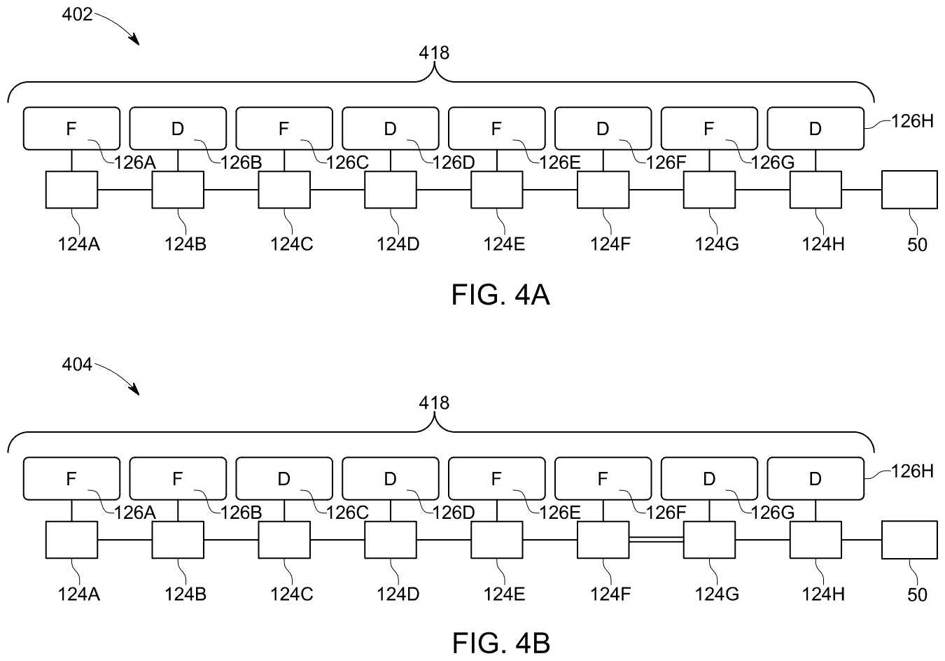

To further illustrate how the present embodiments operate, FIG. 4A shows one configuration of a linear accelerator having switchable quadrupoles, while FIG. 4B shows another configuration of a linear accelerator having switchable quadrupoles. In FIG. 4A, a linear accelerator 418 is shown, having eight acceleration stages (not separately shown). The acceleration stages are represented by the quadrupoles (126A-126H), which quadrupoles may be assumed to alternate with acceleration stages in position along the linear accelerator 418. Moreover, each of the quadrupoles is controlled by a respective quadrupole switch assembly (124A-124H). In the configuration of FIG. 4A, the quadrupole configuration shown is a so-called FODOFODO configuration, where, for a given direction, such as the x-direction, the sequence of focusing of successive quadrupoles follows the sequence of focus (F), defocus (D), focus, defocus, and so forth. This sequence may continue at each acceleration stage of the linear accelerator 418.

In the configuration of FIG. 4B, the quadrupole configuration is a so-called FOFODODO configuration, where, for a given direction, such as the x-direction, the sequence of focusing of successive quadrupoles follows the sequence of focus (F), focus, defocus, defocus. This sequence may continue at each acceleration stage of the linear accelerator 418. The quadrupole configurations of FIG. 4A and FIG. 4B are merely exemplary, and other configuration are possible. According to various embodiments of the disclosure, the controller 50 and/or controllers within the individual quadrupole switch assemblies (124A-124H) may determine when and how to switch the quadrupole configuration, according to user input, according to determined criteria, and so forth.

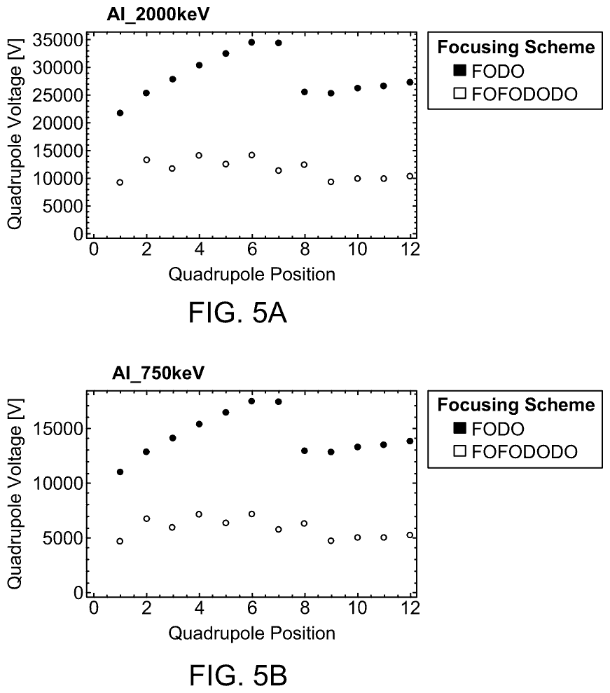

FIG. 5A shows quadrupole applied voltage as a function of position along a linear accelerator for one ion implantation recipe. FIG. 5B shows quadrupole applied voltage as a function of position along a linear accelerator for another ion implantation recipe. In FIG. 5A the implantation recipe calls for the acceleration of the linear accelerator up to ˜2000 keV. The graph of FIG. 5A presents the quadrupole voltage assuming two different quadrupole configurations, generally as depicted in FIG. 4A and FIG. 4B, respectively. Moreover, a total of 12 quadrupoles are assumed. Under these conditions, using the FOFODODO configuration, the quadrupole voltage remains relatively lower, in a range of ˜10 keV to 15 keV at all quadrupoles. Using the FODOFODO configuration, the quadrupole voltage increases substantially as a function of position between the first quadrupole and the sixth quadrupole. approaching 35 kV. The voltage then drops to a value in the range of 25 keV for higher number quadrupoles. Assuming that a target value of 20 keV or less is desirable for operating the quadrupoles, the FOFODODO configuration may provide a suitable option for operating a linear accelerator under the conditions of 2000 keV maximum energy. Thus, the linear accelerator 118 may be adjusted to such a configuration according to the present embodiments.

Referring to FIG. 5B, the implantation recipe calls for the acceleration of the linear accelerator up to ˜750 keV. Under these conditions, using the FOFODODO configuration, the quadrupole voltage remains relatively lower, in a range of ˜5 keV to 7 keV at all quadrupoles. Using the FODOFODO configuration, the quadrupole voltage increases substantially as a function of position between the first quadrupole and the sixth quadrupole. approaching 17 kV. The voltage then drops to a value in the range of 12-13 keV for higher number quadrupoles. Assuming that a target value of 20 keV or less is desirable for operating the quadrupoles, the FODOFODO and FOFODODO configurations allow operating a linear accelerator under the conditions of 750 keV maximum energy. However, because FODOFODO configuration may generally generate a tighter, higher quality ion beam that using the FOFODODO configuration, the FODOFODO configuration may be more suitable for this condition. Thus, for processing a beam to be accelerated to 750 keV, the linear accelerator 118 may be adjusted to the FODOFODO configuration according to the present embodiments.

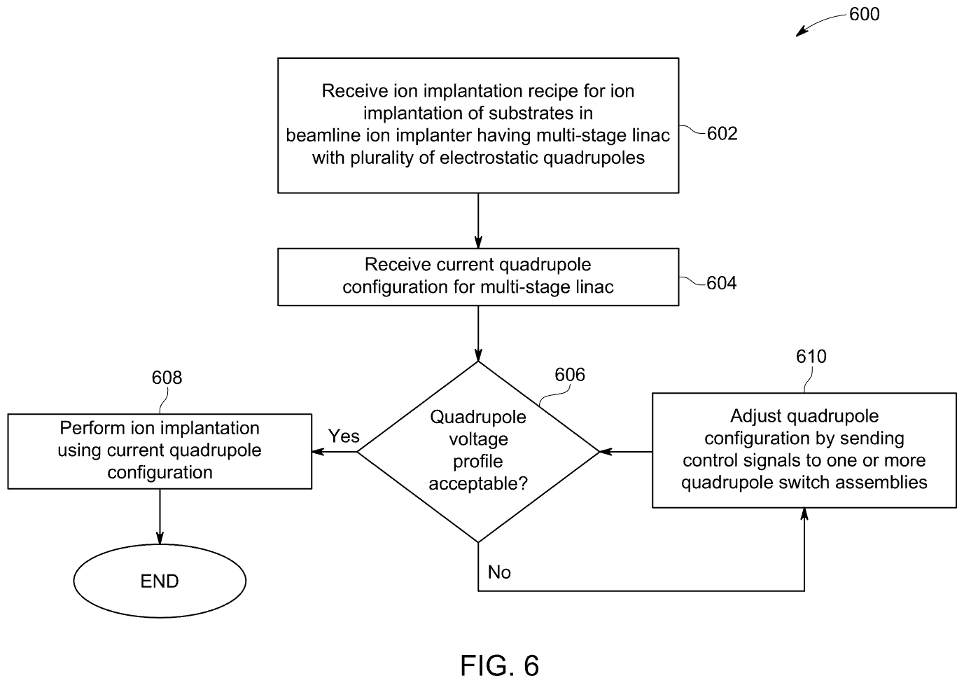

FIG. 6 depicts one exemplary process flow 600. At block 602, an ion implantation recipe for ion implantation of substrates is received in a beamline ion implanter that has a multi-stage LINAC with a plurality of electrostatic quadrupoles.

At block 604, a current quadrupole configuration is received or optionally is determined for the quadrupoles of the LINAC.

At decision block 606, a determination is made as to whether the current quadrupole voltage profile is acceptable. The quadrupole voltage profile may refer to the operating voltages for the electrodes of the different quadrupoles of the linear accelerator. In particular, the current quadrupole voltage profile may refer to the operating voltages of the different quadrupoles for the current quadrupole configuration, and given the ion implantation recipe.

If, at decision block 606, the decision is affirmative, the flow proceeds to block 608, where ion implantation is performed using the current quadrupole configuration. If, at decision block 606, the decision is negative, the flow proceeds to block 610. For example, the current quadrupole configuration may be deemed unacceptable if the current quadrupole configuration, based upon the received ion implantation recipe, specifies an electrode voltage on at least one quadrupole of the linear accelerator that exceeds a determined threshold, such as 15 kV, 20 kV, 25 kV, and so forth. At block 610, the quadrupole configuration is adjusted by sending control signals to one or more quadrupole switch assemblies of the linear accelerator. In this manner, at least one quadrupole will be adjusted between a FO configuration and a DO configuration. In one example, at block 610, the current quadrupole configuration may be a FODOFODO configuration that generates a quadrupole voltage profile resulting in excessive voltage on at least one quadrupole. The decision may be to adjust the quadrupole configuration by adjusting a plurality of quadrupoles of the linear accelerator, resulting in a FOFODODO configuration. The flow then returns to decision block 606.

In view of the above, a first advantage afforded by the present embodiments is that the present embodiments enable changes in quadrupoles focusing arrangement used by different recipes during production tunes. This flexibility may allow optimization of the tradeoff between generating suitable ion beam quality while maintaining acceptable quadrupole voltages. Another advantage of the present embodiments is that the present embodiments enable an extremely flexible recipe generation process where the quadrupole focusing scheme may be any combination of FO configuration and DO configuration. One particular advantage provided by the present embodiments is the flexibility to select the best quadrupole focusing configuration for a given ion energy, such as choosing a FOFODODO configuration for a relatively higher ion energy, and a FODO configuration for a relatively lower ion energy, as detailed herein.

While certain embodiments of the disclosure have been described herein, the disclosure is not limited thereto, as the disclosure is as broad in scope as the art will allow and the specification may be read likewise. Therefore, the above description are not to be construed as limiting. Those skilled in the art will envision other modifications within the scope and spirit of the claims appended hereto.

1. An ion implanter, comprising:
an ion source, to generate a continuous ion beam;
a linear accelerator, comprising a buncher, to receive the continuous ion beam and generate a bunched ion beam, and further comprising a plurality of acceleration stages, arranged to receive the bunched ion beam and accelerate the bunched ion beam;
a plurality of quadrupoles, arranged in alternating fashion with the plurality of acceleration stages; and
a plurality of quadrupole switch assemblies, coupled to the plurality of plurality of quadrupoles, respectively, wherein a given quadrupole switch assembly comprises a polarity switching circuit.

2. The ion implanter of claim 1, wherein a given quadrupole switch assembly comprises:
a switch controller; coupled to a given quadrupole; and
a quadrupole polarity switch circuit, arranged to switch a polarity of a set of electrodes on the given quadrupole.

3. The ion implanter of claim 2, wherein the switch controller is arranged to switch the given quadrupole from a focus configuration to a defocus configuration, wherein in the focus configuration the given quadrupole focuses the ion beam along a first direction, and in the defocus configuration, the given quadrupole defocuses the bunched ion beam along the first direction.

4. The ion implanter of claim 3, further comprising a system controller arranged to control the plurality of quadrupole switch assemblies to switch from a first focusing sequence to a second focusing sequence, wherein the second focusing sequence differs from the first focusing sequence, wherein at least the given quadrupole is switched between the focus and the defocus configuration.

5. The ion implanter of claim 2, wherein the given quadrupole comprises a first pair of opposing electrodes, arranged to generate a first electric field along a first direction, a second pair of opposing electrodes, arranged to generate a second electric field along a second direction, perpendicular to the first direction.

6. The ion implanter of claim 5, wherein the quadrupole polarity switch circuit comprises:
a positive voltage supply to output a positive voltage;
a negative voltage supply to output a negative voltage;
a first switch, coupled to the first pair of opposing electrodes, the first switch comprising a normally closed input and a normally open input; and
a second switch, coupled to the second pair of opposing electrodes, the second switch comprising a second normally closed input and a second normally open input,
wherein the switch controller is directly coupled to the first switch and the second switch between a first state where a first voltage polarity is applied to the first pair of opposing electrodes, and a second voltage polarity is applied to the second pair of opposing electrodes, and a second state, where the second voltage polarity is applied to the first pair of opposing electrodes, and the first voltage polarity is applied to the second pair of opposing electrodes.

7. The ion implanter of claim 6, wherein:
the positive voltage supply is directly coupled to the first switch, the second switch, and to a ground;
the negative voltage supply is directly coupled to the first switch, the second switch and to the ground;
the normally closed input of the first switch is coupled to the normally open input of the second switch; and
the normally open input of the first switch is coupled to the normally closed input of the second switch.

8. The ion implanter of claim 6, wherein the quadrupole polarity switch circuit comprises:
a floating voltage supply;
a first switch, coupled to the floating voltage supply and to the quadrupole; and
a second switch, coupled to the floating voltage supply and to a ground.

9. The ion implanter of claim 8, wherein:
the normally closed input of the first switch is coupled to the normally open input of the second switch; and
the normally open input of the first switch is coupled to the normally closed input of the second switch.

10. A control arrangement for operating a linear accelerator, comprising:
a plurality of quadrupole switch assemblies, coupled to a plurality of quadrupoles, respectively, the plurality of quadrupoles being arranged in alternating fashion with a plurality of acceleration stages of the linear accelerator,
wherein a given quadrupole switch assembly comprises:
a quadrupole polarity switch circuit, arranged to switch a polarity of a given quadrupole of the plurality of quadrupoles; and
a switch controller, coupled to the quadrupole polarity switch circuit, the switch controller comprising:
a processor; and
a memory unit coupled to the processor, including a quadrupole switching routine, the quadrupole switching routine operative on the processor to control the quadrupole polarity switch circuit to switch the given quadrupole from a focus configuration to a defocus configuration.

11. The control arrangement of claim 10, wherein the quadrupole switching routine is operative to switch the given quadrupole, responsive to user input

12. The control arrangement of claim 10, wherein the quadrupole switching routine is operative on the processor to switch the given quadrupole according to a set of determined criteria.

13. The control arrangement of claim 10, wherein the quadrupole switching routine is operative on the processor to control the plurality of quadrupole switch assemblies to switch from a first focusing sequence to a second focusing sequence, wherein the second focusing sequence differs from the first focusing sequence, wherein at least the given quadrupole is switched between the focus and the defocus configuration.

14. The control arrangement of claim 10, wherein the quadrupole polarity switch circuit comprises:
a positive voltage supply to output a positive voltage;
a negative voltage supply to output a negative voltage;
a first switch, coupled to a first pair of opposing electrodes, the first switch comprising a normally closed input and a normally open input; and
a second switch, coupled to a second pair of opposing electrodes, the second switch comprising a second normally closed input and a second normally open input,
wherein the switch controller is directly coupled to the first switch and the second switch between a first state where a first voltage polarity is applied to the first pair of opposing electrodes, and a second voltage polarity is applied to the second pair of opposing electrodes, and a second state, where the second voltage polarity is applied to the first pair of opposing electrodes, and the first voltage polarity is applied to the second pair of opposing electrodes.

15. The control arrangement of claim 14, wherein:
the positive voltage supply is directly coupled to the first switch, the second switch, and to a ground;
the negative voltage supply is directly coupled to the first switch, the second switch and to the ground;
the normally closed input of the first switch is coupled to the normally open input of the second switch; and
the normally open input of the first switch is coupled to the normally closed input of the second switch.

16. The control arrangement of claim 10, wherein the quadrupole polarity switch circuit comprises:
a floating voltage supply;
a first switch, coupled to the floating voltage supply and to the quadrupole; and
a second switch, coupled to the floating voltage supply and to a ground.

17. The control arrangement of claim 15, wherein:
the normally closed input of the first switch is coupled to the normally open input of the second switch; and
the normally open input of the first switch is coupled to the normally closed input of the second switch.

18. A method of operating an ion implanter, comprising:
receiving an ion implantation recipe for implementing in the ion implanter, the ion implanter comprising a multi-stage linear accelerator having a plurality of quadrupoles;
receiving a current quadrupole configuration for the plurality of quadrupoles;
receiving a current quadrupole voltage profile, comprising a plurality of voltages that are applied to electrodes of the plurality of quadrupoles, respectively; and
adjusting the current quadrupole configuration by sending at least one control signal to one or more quadrupole switch assemblies of the linear accelerator, when the current quadrupole voltage profile exceeds a determined threshold.

19. The method of claim 18, wherein the plurality of quadrupoles comprises a plurality of electrostatic quadrupoles, and wherein the adjusting the current quadrupole configuration comprises changing at least one electrostatic quadrupole between a focus configuration and a defocus configuration for a given direction.
